(19) United States
(12) Patent Application Publication
(10) Pub. No.: US 2016/0276578 A1
(43) Pub. Date: Sep. 22, 2016

(54) DEVICE INCLUDING MAGNETORESISTIVE ELEMENT AND MEMORY CHIP

(71) Applicant: KABUSHIKI KAISHA TOSHIBA, Tokyo (JP)

(72) Inventors: Yosuke KOBAYASHI, Yokohama Kanagawa (JP); Kenji NOMA, Yokkaichi Mie (JP); Takeshi FUJIMORI, Chigasaki Kanagawa (JP)

(73) Assignee: KABUSHIKI KAISHA TOSHIBA, Tokyo (JP)

(21) Appl. No.: 14/730,882

(22) Filed: Jun. 4, 2015

Related U.S. Application Data
(60) Provisional application No. 62/135,031, filed on Mar. 18, 2015.

(51) Int. Cl. H01L 43/08; H01L 43/10; H01L 43/02

(52) U.S. Cl. CPC H01L 43/08; H01L 43/02; H01L 43/10

(57) ABSTRACT

According to one embodiment, a device including a magnetoresistive element is disclosed. The device includes a substrate, a second layer provided on the substrate and including a magnetic material, and a third layer provided on a top or bottom of the second layer and including a material having a negative coefficient of thermal expansion.

### CROSS-REFERENCE TO RELATED APPLICATIONS

This application claims the benefit of U.S. Provisional Application No. 62/135,031, filed Mar. 18, 2015, the entire contents of which are incorporated herein by reference.

### FIELD

Embodiments described herein relate generally to a device including a magnetoresistive element and a memory chip.

### BACKGROUND

As one of memory elements using a magnetoresistive element, a magnetic random access memory (MRAM) using a ferromagnetic material as a magnetic material is known. The MRAM comprises a magnetic tunnel junction (MTJ) element which uses the tunneling magnetoresistive (TMR) effect as a storage element, and stores information by the magnetization state of the MTJ element.

### BRIEF DESCRIPTION OF THE DRAWINGS

FIG. 1 is a cross-sectional view schematically showing a device according to an embodiment;

FIG. 2A is an illustration showing an RH loop with a magnetic field offset;

FIG. 2B is an illustration showing an RH loop without magnetic field offset;

FIG. 3 is an illustration schematically showing a stress generated in the device of FIG. 1;

FIG. 4 is a table showing materials having negative coefficients of linear thermal expansion;

FIG. 5 is a plan view schematically showing a magnetic memory according to an embodiment;

FIG. 6 is a cross-sectional view taken along broken line 6-6 of FIG. 5;

FIG. 7 is a cross-sectional view taken along broken line 7-7 of FIG. 5;

FIG. 8 is a plan view schematically showing a device according to another embodiment;

FIG. 9 is a cross-sectional view taken along broken line 9-9 of FIG. 8;

FIG. 10 is a plan view schematically showing a device according to yet another embodiment;

FIG. 11 is a plan view schematically showing a device according to yet another embodiment;

FIG. 12 is a cross-sectional view schematically showing a device according to yet another embodiment;

FIG. 13 is a cross-sectional view schematically showing a device according to yet another embodiment;

FIG. 14 is a cross-sectional view schematically showing a device according to yet another embodiment;

FIG. 15 is a cross-sectional view schematically showing a device according to yet another embodiment;

FIG. 16A is a plan view schematically showing a wafer according to an embodiment; and

FIG. 16B is a cross-sectional view taken along broken line 16B-16B of FIG. 16A.

### DETAILED DESCRIPTION

In general, according to one embodiment, a device including a magnetoresistive element is disclosed. The device includes a substrate; a second layer provided on the substrate and including a magnetic material; and a third layer provided on a top or bottom of the second layer and including a material having a negative coefficient of thermal expansion.

In general, according to one embodiment, a memory chip is disclosed. The memory chip includes a substrate; a first layer provided on the substrate and including a magnetoresistive element; a second layer provided on the first layer and including a magnetic material; and a third layer provided on a top or bottom of the second layer and including a material having a negative coefficient of thermal expansion.

Embodiments will be described hereinafter with reference to the accompanying drawings. The dimension, the ratio, etc., in each of the drawings are not necessarily the same as those in reality. In the drawings, the same portions or corresponding portions are denoted by the same reference numbers (including a different subscript). In addition, duplicated descriptions are given as necessary.

### First Embodiment

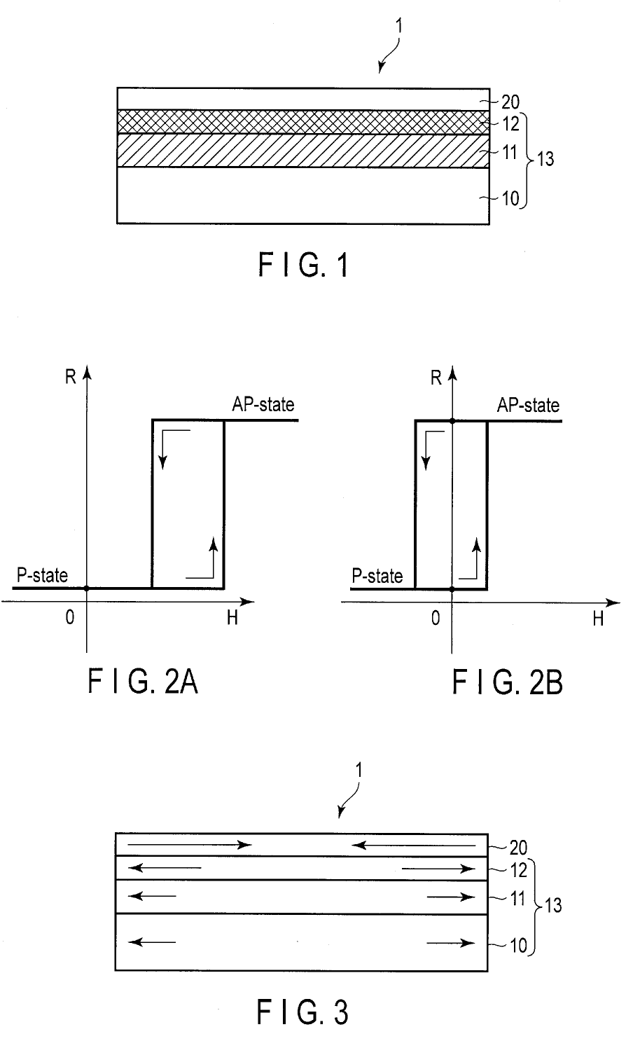

FIG. 1 is a cross-sectional view schematically showing a device 1 according to an embodiment. The device 1 is, for example, a chip including a magnetic memory (memory chip). The device 1 includes a substrate 10, a magnetic memory layer (a first layer) 11 provided on the substrate 10 and including a magnetic memory comprising a plurality of MTJ elements, a magnet layer (a second layer) 12 provided on the magnetic memory layer 11 and applying a magnetic field to the plurality of MTJ elements, and a layer (a third layer) 20 provided for a stacked body 13 which includes the substrate 10, the magnetic memory layer 11 and the magnet layer 12, and including a material having a negative coefficient of thermal expansion.

The MTJ element includes a storage layer, a reference layer, and a tunnel barrier layer provided between the storage layer and the reference layer.

A magnetic field offset may be generated in the MTJ element. The magnetic field offset refers to a status in which a leakage magnetic field generated in the MTJ element cannot be completely cancelled, and a loop of resistance change of the MTJ element to an external magnetic field (hereinafter referred to as an R-H loop) is shifted in a positive direction (or negative direction) of the magnetic field.

For example, the R-H loop of FIG. 2A is offset in the positive direction, and the MTJ element can only be in the P-state (low resistance state) under the zero magnetic field (H=0). In this state, a cell resistance value can only take one value, and a memory operation (a binary operation) cannot be performed.

In order to resolve the magnetic field offset, it is effective to shift the R-H loop in the opposite direction of the magnetic field offset by externally applying a magnetic field (an external magnetic field) to the MTJ element. This enables the MTJ element to have two values of the P-state and the AP-state under the zero magnetic field as shown in the R-H loop of FIG. 2B, and the normal memory operation can be performed.

In the present embodiment, the external magnetic field is applied to the MTJ element by the magnet layer 12. The magnet layer 12 includes magnet. The material of the magnet is, for example, CoCr, CoPt, FePt, SmCo, and NdFe. When a CoCr magnet is used, it is necessary for the thickness of the CoCr magnet to be several tens to several hundreds of μm, for example, to cancel the magnetic field offset of the MTJ element.

As the substrate 10, for example, an Si substrate is used. Si has a positive coefficient of linear thermal expansion, and its value is about 3×10⁻⁶/K. Meanwhile, as the magnet layer 12, a CoCr magnet, for example is used, as described above. CoCr also has a positive coefficient of linear thermal expansion, and the value is about 11.4×10⁻⁶/K. That is, a difference between the coefficient of linear thermal expansion of the substrate 10 and that of the magnet layer 12 is large. Accordingly, when the temperature of the device 1 is increased, the CoCr magnet distorts more than the Si substrate, so that a large tensile stress is generated on the side of the surface of the Si substrate. As a result, the stacked body 13 may be warped.

As described above, when the CoCr magnet is used, it is necessary for the thickness of the magnet layer 12 to be several tens to a hundred of μm. The magnet layer 12 being thick as described above increases warping due to the aforementioned difference between the coefficients of linear thermal expansion. For example, when the temperature of the Si substrate reaches about 100° C., large warping of the order of several millimeters may occur in the Si substrate. The warping can be acquired by, for example, measuring a gap between the Si substrate placed on a surface plate and the surface plate. The rise in the temperature of the Si substrate is caused by, for example, heat generation of a CPU included in the device 1.

When the stacked body 13 warps, the characteristics of the MTJ element changes, and the magnetic memory may not operate normally. The change of the characteristics of the MTJ element is, for example, that the MTJ element changes from the state of FIG. 2B to the state of FIG. 2A.

Hence, in the present embodiment, the stacked body 13 comprises a layer including a material having a negative coefficient of linear thermal expansion (hereinafter referred to as a stress cancellation layer) 20 to reduce stress by the difference between the coefficients of linear thermal expansion that causes the stacked body 13 to warp. In the present embodiment, the stress cancellation layer 20 is provided on the magnet layer 12.

FIG. 3 is an illustration schematically showing a stress generated in the heated device 1. Since normal materials have the positive coefficient of linear thermal expansion, the materials expands and the volume increases by heating. The positive coefficient of linear thermal expansion of the magnet layer 12 is greater than that of the substrate 10 and the memory layer 11, and the tensile stress is generated in the stacked body 13. However, the stress cancellation layer 20 has the negative coefficient of linear thermal expansion, and the stress cancellation layer 20 contacts and the volume reduces by heating. Accordingly, a compressive stress is given to the stacked body 13. As a result, a net stress generated in the stacked body 13 is reduced, and warping of the stacked body 13 is reduced.

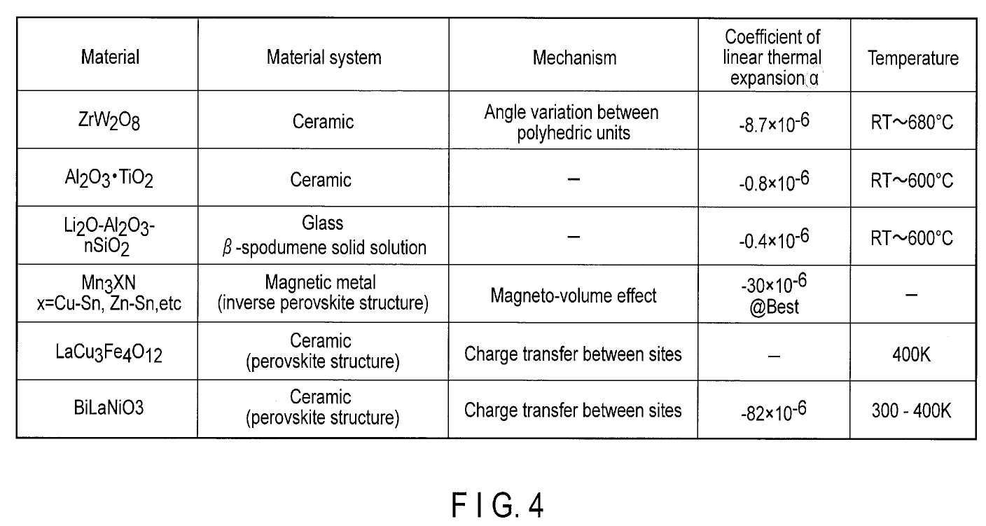

As a material having the negative coefficient of linear thermal expansion, the materials shown in FIG. 4, are known for instance. The material system includes ceramic, glass, magnetic metal, etc. The absolute value of a coefficient of thermal expansion of a mixture of Al₂O₃ and TiO₂, or Li₂O-Al₂O₃-nSiO₂ is smaller than that of CoCr. In contrast, the materials such as magnetic metal Mn₃XN and BiLaNiO₃ of a perovskite ceramic are, α≧10×10⁻⁶, and these materials have the negative coefficient of linear thermal expansion that is sufficient to cancel the thermal stress of CoCr (the material of the magnet layer 12). The materials shown in FIG. 4 can be formed by using sputtering process, for example. Moreover, the materials other than Mn₃XN can be formed by using sol-gel method. Further, as a material having the negative coefficient of linear thermal expansion, a material including at least two types of materials shown in FIG. 4 may be used.

The thickness of the magnet layer 12 is determined depending on the degree of the magnetic field offset of the MTJ element. When the thickness of the magnet layer 12 is changed, the magnitude of thermal expansion of the magnet layer 12 is also changed, so the magnitude of thermal contraction of the stress cancellation layer 20 is tuned in accordance with the thickness of the magnet layer 12. The magnitude of thermal contraction (stress) of the stress cancellation layer 20 can be adjusted in accordance with the material having the negative coefficient of linear thermal expansion used for the stress cancellation layer 20 (i.e., the magnitude of the negative coefficient of linear thermal expansion), and the thickness or the like of the stress cancellation layer 20. The magnitude of stress (compressive stress) of the stress cancellation layer 20 can be estimated by the product of effective thickness of the stress cancellation layer 20 and linear thermal expansion coefficient α. The effective thickness of the stress cancellation layer 20 and the linear thermal expansion coefficient α are selected such that the sum of total stress (tensile stress) of each of the layers constituting the stacked body 13 and the stress (the compressive stress) of cancellation layer 20 approaches zero. As in the case of the stress cancellation layer 20, the stress (tensile stress) of each of the layers constituting the stacked body 13 can be estimated by the product of an effective thickness of the layer and the coefficient of linear thermal expansion.

Next, an example of the magnetic memory in the magnetic memory layer 11 will be described.

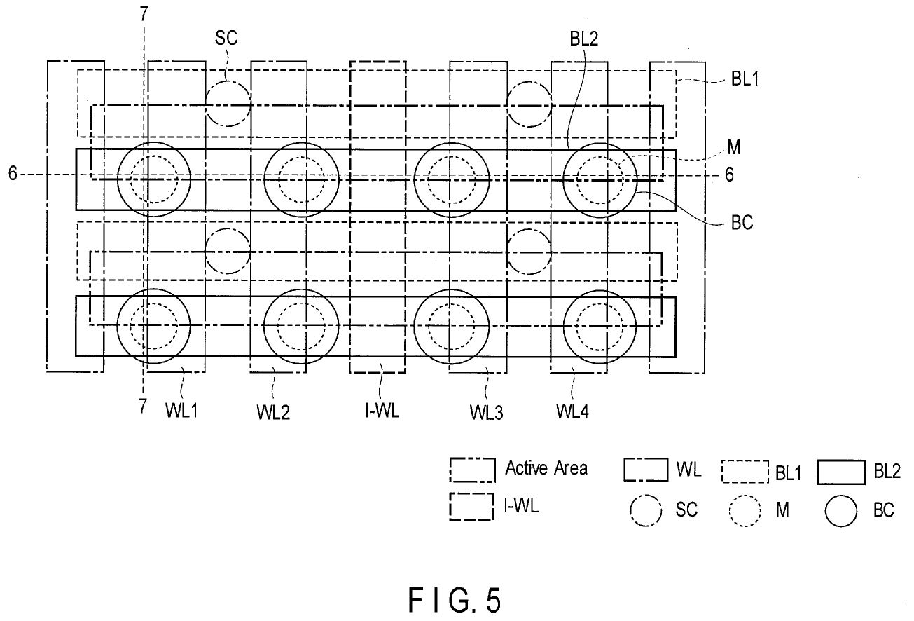

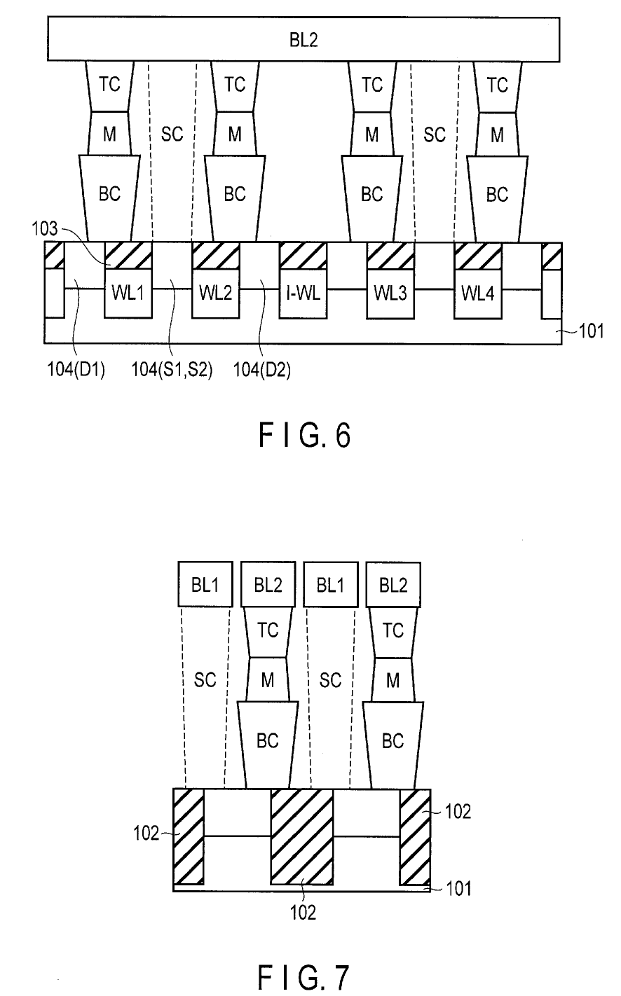

FIG. 5 is a plan view schematically showing the magnetic memory according to an embodiment, FIG. 6 is a cross-sectional view taken along line 6-6 of FIG. 5, and FIG. 7 is a cross-sectional view taken along broken line 7-7 of FIG. 5. The magnetic memory of the present embodiment is a magnetoresistive random access memory (MRAM) which uses an MTJ element as a storage element.

In the drawings, 101 indicates a silicon substrate (semiconductor substrate), and an element isolation region 102 is formed in a surface of the silicon substrate 101. The element isolation region 102 defines active areas.

The MRAM of the present embodiment comprises a first select transistor in which a gate electrode is a word line WL1, a first MTJ element M connected to one source/drain region 104 (drain region D1) of the first select transistor, a second select transistor in which a gate electrode is a word line WL2, and a second MTJ element M connected to one source/drain region 104 (drain region D2) of the second select transistor. In the drawings, 103 indicates a cap insulating film.

That is, one memory cell of the embodiment is constituted of one MTJ (memory element) and one select transistor, and two select transistors of the two neighboring memory cells share the other source/drain region 104 (source regions S1, S2).

The gate (gate insulating film, gate electrode) of the select transistor of the present embodiment is buried in the surface of the silicon substrate 101.

That is, the gate of the present embodiment has a buried gate (BG) structure. Similarly, the gate(word line I-WL) for element isolation has the BG structure.

One source/drain region 104 (D1) of the first select transistor is connected to a lower part of the first MTJ element M via a plug BC. An upper part of first MTJ element M is connected to a bit line BL2 via a plug TC.

The other source/drain region 104 (S1) of the first select transistor is connected to a bit line BL1 via a plug SC.

In the present embodiment, while planar patterns of the plug BC, the MTJ element M, the plug TC, and the plug SC are circular, however, other shapes may be employed.

One source/drain region 104 (D2) of the second select transistor is connected to a lower part of second MTJ element M via plug a BC. An upper part of second MTJ element M is connected to bit line BL2 via a plug TC.

The other source/drain region 104 (S2) of the second select transistor is connected to the bit line BL1 via the plug SC.

The first select transistor, the first MTJ element M, the second select transistor, and the second MTJ element M (two memory cells) are provided in each active areas. The two neighboring active areas are isolated by the element isolation region 102.

Word lines WL3 and WL4 correspond to the word lines WL1 and WL2, respectively. Therefore, two memory cells are constituted by the first select transistor in which word the line WL3 is the gate, the first MTJ element M connected to one source/drain region of the first select transistor, the second select transistor in which the word line WL2 is the gate, and the second MTJ element M connected to one source/drain region of the second select transistor.

The magnetic memory of the present embodiment will now be described according to its manufacturing method. FIGS. 4 to 12 are cross-sectional views for describing the method of manufacturing the magnetic memory of the present embodiment.

In the case of the device 1 of FIG. 1, when viewed from above, the area of the stress cancellation layer 20 is the same as the area of each of the substrate 10, the magnetic memory layer 11, and the magnet layer 12.

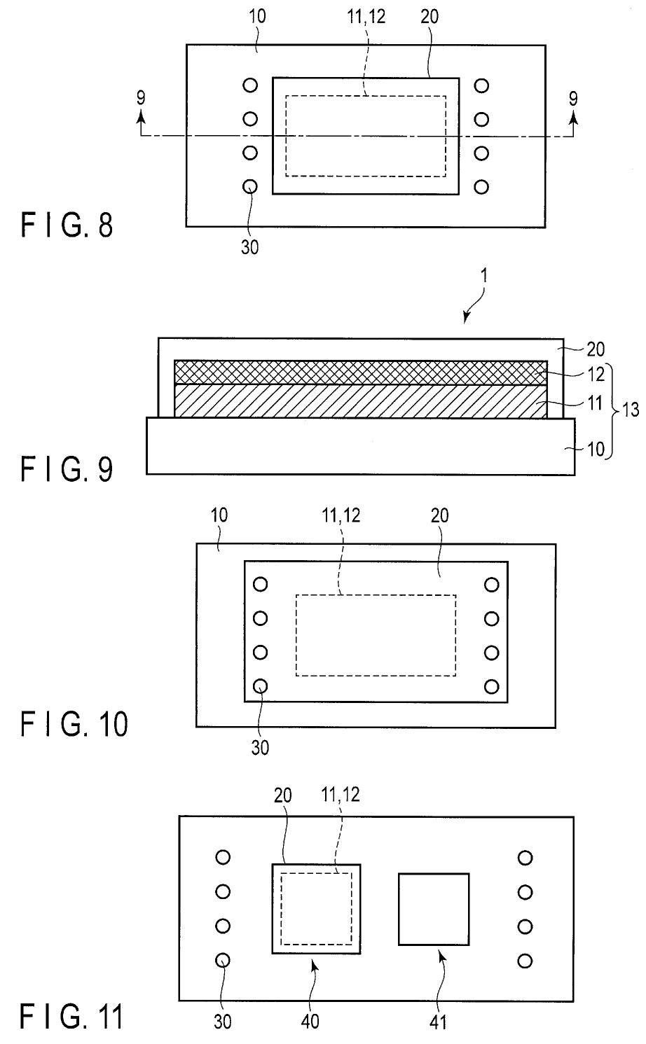

However, as shown in FIG. 8, the area of the stress cancellation layer 20 may be greater than the area of each of the magnetic memory layer 11 and the magnet layer 12. In this case, the magnetic memory layer 11 and the magnet layer 12 are covered by the stress cancellation layer 20, as shown in FIG. 9. It is note that a reference number 30 in FIG. 8 indicates a pad.

Alternatively, as shown in FIG. 10, the area of the stress cancellation layer 20 may be of a size to further cover the pad electrodes 30.

FIG. 11 is a plan view showing an example of an embedded LSI according to an embodiment. A chip 40 including the magnetic memory layer 11, the magnet layer 12, and the stress cancellation layer 20, and a chip 41 including a logic circuit are mounted on the substrate 10. The stress cancellation layer 20 is not provided on the chip 41.

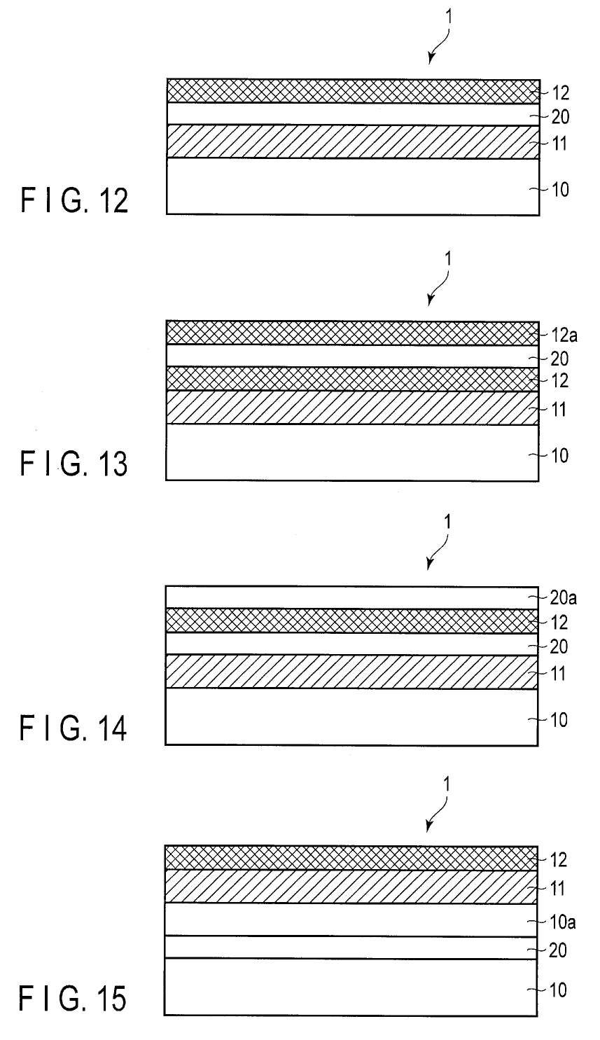

FIGS. 12 to 15 are cross-sectional views showing a device 1 according to other embodiments.

FIG. 12 shows an example in which a magnet layer 12 is provided on a magnetic memory layer 11 via a stress cancellation layer 20. In other words, the device 1 of FIG. 12 is different from the device 1 of FIG. 1 in that the positional relationship between the magnet layer 12 and the stress cancellation layer 20 is upside down.

A device 1 of FIG. 13 is different from the device 1 of FIG. 1 in that the device 1 of FIG. 13 further comprises a magnet layer 12a provided on the stress cancellation layer 20. The material of the magnet layer 12a may be the same as the material of the magnet layer 12 or different from that of the magnet layer 12.

A device 1 of FIG. 14 is different from the device 1 of FIG. 1 in that the device 1 of FIG. 14 further comprises a stress cancellation layer (a fourth layer) 20a provided on a magnet layer 12. The material of the stress cancellation layer 20a may be the same as the material of the stress cancellation layer 20 or different from that of the stress cancellation layer 20.

A device 1 of FIG. 15 is different from the device 1 of FIG. 1 in that a stress cancellation layer 20 is provided under a magnetic memory layer 11. A single crystal semiconductor layer (for example, an single crystal Si layer) 10a is provided between the magnetic memory layer 11 and the stress cancellation layer 20. When the stress cancellation layer 20 is an insulating layer, the substrates 12, 20, and 10a are realized by using the technology of an SOI substrate.

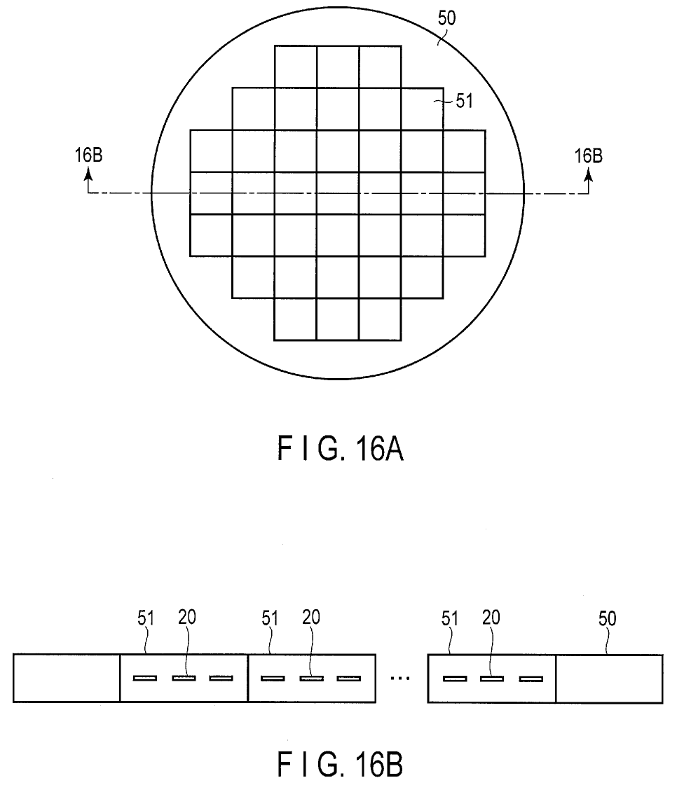

FIG. 16A is a plan view of a wafer 50 according to an embodiment, and FIG. 16B is a cross-sectional view taken along line 16B-16B of FIG. 16A.

A plurality of chip regions 51 are provided on the wafer 50. A scribe line which is not shown is provided between the chip regions 51. Each of the chip regions 51 includes the device (the magnetic memory) of the aforementioned embodiments. Therefore, the device of each of the chip regions 51 includes the stress cancellation layer 20.

After forming the magnetic memory, a high-temperature wafer test which exceeds 100° C. is generally performed. Accordingly, generally, the wafer is warp by the high-temperature wafer test.

However, since each of the chip regions 51 in the wafer 50 includes the stress cancellation layer 20, warping of the wafer 50 is restrained even if the high-temperature wafer test is performed.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A device including a magnetoresistive element comprising:
a substrate;
a first layer provided on the substrate and including the magnetoresistive element;
a second layer provided on the first layer and including a magnetic material; and
a third layer provided on a top or bottom of the second layer and including a material having a negative coefficient of thermal expansion.

2. The device according to claim 1, wherein the second layer has a positive coefficient of thermal expansion.

3. The device according to claim 1, wherein the second layer includes Co or Fe.

4. The device according to claim 3, wherein the second layer further includes Pt, Sm, or Nd.

5. The device according to claim 1, wherein the substrate has a positive coefficient of thermal expansion.

6. The device according to claim 1, wherein the substrate includes Si.

7. The device according to claim 1, wherein the material having the negative coefficient of thermal expansion includes ZrW₂O₈, a mixture of Al₂O₃ and TiO₂, LiO₂-Al₂O₃-nSiO₂-based glass, Mn₃XN (X═Cu-Sn or Zn-Sn), LaCu₃Fe₄O₁₂, or BiLaNiO₃.

8. The device according to claim 1, wherein the third layer is provided on an upper surface of the second layer.

9. The device according to claim 8, wherein the third layer is further provided on a side surface of the second layer.

10. The device according to claim 1, wherein the third layer is provided between the second layer and the first layer.

11. The device according to claim 1, wherein the third layer is provided between the first layer and the second layer, and further comprising a fourth layer provided on an upper surface of the second layer and including a magnetic material.

12. The device according to claim 1, wherein the third layer is provided between the substrate and the first layer, and further comprising a semiconductor layer provided between the third layer and the first layer.

13. The device according to claim 1, wherein the device further comprises a circuit provided on the substrate, and the third layer is not provided on the circuit.

14. The device according to claim 1, wherein the magnetoresistive element constitutes a magnetic memory.

15. The device according to claim 1, wherein each of the substrate, the first layer, and the second layer generates a tensile stress by heat.

16. The device according to claim 1, wherein the third layer generates a compressive stress by heat.

17. The device according to claim 11, wherein the fourth layer generates a compressive stress by heat.

18. A memory chip comprising:
a substrate;
a first layer provided on the substrate and including a magnetoresistive element;
a second layer provided on the first layer and including a magnetic material; and
a third layer provided on a top or bottom of the second layer and including a material having a negative coefficient of thermal expansion.

19. The chip according to claim 18, wherein the second layer has a positive coefficient of linear thermal expansion.

20. The chip according to claim 18, wherein the substrate has a positive coefficient of linear thermal expansion.

21. The chip according to claim 18, wherein the material having the negative coefficient of thermal expansion includes ZrW₂O₈, a mixture of Al₂O₃ and TiO₂, LiO₂-Al₂O₃-nSiO₂-based glass, Mn₃XN (X═Cu-Sn or Zn-Sn), LaCu₃Fe₄O₁₂, or BiLaNiO₃.
